(19) United States
(12) Patent Application Publication
(10) Pub. No.: US 2024/0405787 A1
(43) Pub. Date: Dec. 5, 2024

(54) POLARIZATION-ADJUSTED CONVOLUTIONAL CODES WITH FREEZER

(71) Applicant: Samsung Electronics Co., Ltd., Suwon-si (KR)

(72) Inventors: Heping Wan, Plano, TX (US); Joonyoung Cho, Portland, OR (US); Jianzhong Zhang, Dallas, TX (US); Soheil Rostami, Carrollton, TX (US)

(21) Appl. No.: 18/619,049

(22) Filed: Mar. 27, 2024

Related U.S. Application Data
(60) Provisional application No. 63/469,750, filed on May 30, 2023.

(51) Int. Cl. H03M 13/23; H04L 1/00

(52) U.S. Cl. CPC H03M 13/235; H04L 1/0041; H04L 1/0045; H04L 1/0059

(57) ABSTRACT

Error-correcting performance of polarization-adjusted convolutional codes is improved by refreezing low weight indices. For information bits (k), where k is a positive integer, a plurality of convolutionally encoded bits (n) are generated by performing a convolutional encoding operation on the plurality of information bits and a plurality of frozen bits (n−k), where n is a positive integer. A refreezing operation is performed on the convolutionally encoded bits, including dynamically assigning zeros to selected frozen indices such that a number of low weight codewords is reduced. Polar encoded bits are generated by performing a polar encoding operation on an output of the refreezing operation, providing polar encoded bits for transmission or storage.

### CROSS-REFERENCE TO RELATED APPLICATION AND PRIORITY CLAIM

This application claims priority under 35 U.S.C. § 119 (e) to U.S. Provisional Patent Application No. 63/469,750 filed on May 30, 2023, which is hereby incorporated by reference in its entirety.

### TECHNICAL FIELD

This disclosure relates generally to polarization-adjusted convolutional (PAC) coding for wireless communication. More specifically, this disclosure relates to improving PAC codes.

### BACKGROUND

The use of computing technology for media processing is greatly expanding, largely due to the usability, convenience, computing power of computing devices, and the like. Portable electronic devices, such as laptops and mobile smart phones are becoming increasingly popular as a result of the devices becoming more compact, while the processing power and resources included in a given device is increasing. Even with the increase of processing power, portable electronic devices often struggle to provide the processing capabilities to handle new services and applications, as newer services and applications often require more resources that is included in a portable electronic device. Thus, improved methods and apparatus for configuring and deploying media processing in the network are needed.

### SUMMARY

This disclosure provides a method and apparatus for improving error-correcting performance of polarization-adjusted convolutional codes by refreezing low weight indices.

In a first embodiment, a method for encoding includes receiving a plurality of information bits (k), where k is a positive integer. The method further includes generating a plurality of convolutionally encoded bits (n) by performing a convolutional encoding operation on the plurality of information bits and a plurality of frozen bits (n−k), where n is a positive integer. The method still further includes performing a refreezing operation on the plurality of convolutionally encoded bits, where the refreezing operation includes dynamically assigning zeros to selected frozen indices such that a number of low weight codewords is reduced. The method also includes generating a plurality of polar encoded bits by performing a polar encoding operation on an output of the refreezing operation. The method includes providing the plurality of polar encoded bits for transmission or storage.

In a second embodiment, an encoding apparatus includes a transmitter and a processor. The processor is configured to receive a plurality of information bits (k), where k is a positive integer. The processor is further configured to generate a plurality of convolutionally encoded bits (n) by performing a convolutional encoding operation on the plurality of information bits and a plurality of frozen bits (n−k), where n is a positive integer. The processor is still further configured to perform a refreezing operation on the plurality of convolutionally encoded bits, where the refreezing operation includes dynamically assigning zeros to selected frozen indices such that a number of low weight codewords is reduced. The processor is also configured to generate a plurality of polar encoded bits by performing a polar encoding operation on an output of the refreezing operation. The resulting plurality of polar encoded bits are provided for transmission or storage.

In a third embodiment, a decoding apparatus includes a transceiver configured to receive a polar code with refrozen indices from a communication channel, and a processor configured to perform successive cancellation list decoding of the polar code with refrozen indices. The polar code with refrozen indices is generated by receiving a plurality of information bits (k), where k is a positive integer, generating a plurality of convolutionally encoded bits (n) by performing a convolutional encoding operation on the plurality of information bits and a plurality of frozen bits (n−k), wherein n is a positive integer, performing a refreezing operation on the plurality of convolutionally encoded bits, wherein the refreezing operation includes dynamically assigning zeros to selected frozen indices such that a number of low weight codewords is reduced, and generating a plurality of polar encoded bits by performing a polar encoding operation on an output of the refreezing operation.

Other technical features may be readily apparent to one skilled in the art from the following figures, descriptions, and claims.

Before undertaking the DETAILED DESCRIPTION below, it may be advantageous to set forth definitions of certain words and phrases used throughout this patent document. The term “couple” and its derivatives refer to any direct or indirect communication between two or more elements, whether or not those elements are in physical contact with one another. The terms “transmit,” “receive,” and “communicate,” as well as derivatives thereof, encompass both direct and indirect communication. The terms “include” and “comprise,” as well as derivatives thereof, mean inclusion without limitation. The term “or” is inclusive, meaning and/or. The phrase “associated with,” as well as derivatives thereof, means to include, be included within, interconnect with, contain, be contained within, connect to or with, couple to or with, be communicable with, cooperate with, interleave, juxtapose, be proximate to, be bound to or with, have, have a property of, have a relationship to or with, or the like. The term “controller” means any device, system, or part thereof that controls at least one operation. Such a controller may be implemented in hardware or a combination of hardware and software and/or firmware. The functionality associated with any particular controller may be centralized or distributed, whether locally or remotely. The phrase “at least one of,” when used with a list of items, means that different combinations of one or more of the listed items may be used, and only one item in the list may be needed. For example, “at least one of: A, B, and C” includes any of the following combinations: A, B, C, A and B, A and C, B and C, and A and B and C.

Moreover, various functions described below can be implemented or supported by one or more computer programs, each of which is formed from computer readable program code and embodied in a computer readable medium. The terms “application” and “program” refer to one or more computer programs, software components, sets of instructions, procedures, functions, objects, classes, instances, related data, or a portion thereof adapted for implementation in a suitable computer readable program code. The phrase “computer readable program code” includes any type of computer code, including source code, object code, and executable code. The phrase “computer readable medium” includes any type of medium capable of being accessed by a computer, such as read only memory (ROM), random access memory (RAM), a hard disk drive, a compact disc (CD), a digital video disc (DVD), or any other type of memory. A “non-transitory” computer readable medium excludes wired, wireless, optical, or other communication links that transport transitory electrical or other signals. A non-transitory computer readable medium includes media where data can be permanently stored and media where data can be stored and later overwritten, such as a rewritable optical disc or an erasable memory device.

Definitions for other certain words and phrases are provided throughout this patent document. Those of ordinary skill in the art should understand that in many if not most instances, such definitions apply to prior as well as future uses of such defined words and phrases.

### BRIEF DESCRIPTION OF THE DRAWINGS

For a more complete understanding of the present disclosure and its advantages, reference is now made to the following description taken in conjunction with the accompanying drawings, in which like reference numerals represent like parts:

FIG. 1 illustrates an example wireless network within which polarization-adjusted convolutional codes with freezer may be implemented according to embodiments of the present disclosure;

FIG. 2 illustrates an example gNB within which polarization-adjusted convolutional codes with freezer may be implemented according to embodiments of the present disclosure;

FIG. 3 illustrates an example UE within which polarization-adjusted convolutional codes with freezer may be implemented according to embodiments of the present disclosure;

FIG. 4A and FIG. 4B illustrate an example of wireless transmit and receive paths, respectively, for transmitting or receiving polarization-adjusted convolutional codes with freezer according to embodiments of the present disclosure;

FIG. 5 illustrates an example of PAC encoder;

FIG. 6 illustrates an example of polarization-adjusted convolutional coding with freezer in accordance with embodiments of the present disclosure;

FIGS. 7A-7B illustrates an example construction of the subset F′ for the freezer in an exemplary embodiment of the present disclosure;

FIG. 8 is a high level flowchart of a process to choose the frozen indices in accordance with embodiments of the present disclosure;

FIG. 9 is a high level flowchart of an alternative process to choose the frozen indices in accordance with embodiments of the present disclosure; and

FIG. 10 compares performance of polar codes with and without the encoding method according to embodiments of the present disclosure.

### DETAILED DESCRIPTION

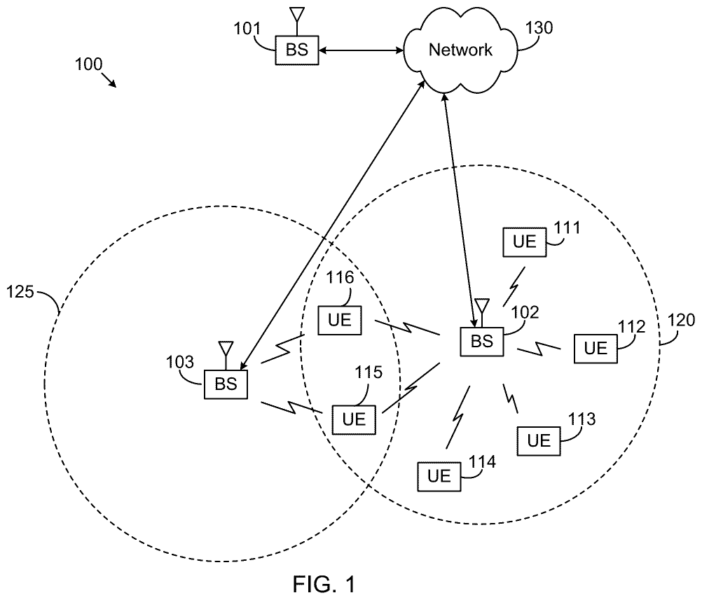

FIGS. 1 through 10, described below, and the various embodiments used to describe the principles of the present disclosure are by way of illustration only and should not be construed in any way to limit the scope of the disclosure. Those skilled in the art will understand that the principles of the present disclosure may be implemented in any type of suitably arranged device or system.

The following references are incorporated herein by reference:
[1] E. Arikan, “Channel Polarization: A Method for Constructing Capacity-Achieving Codes for Symmetric Binary-Input Memoryless Channels,” in IEEE Transactions on Information Theory, vol. 55, no. 7, pp. 3051-373 July 2009.
[2] E. Arikan, “From sequential decoding to channel polarization and back again,” available at https://arxiv.org/abs/1908.09594, August 2019.

A new design for PAC codes is proposed, in which the proposed codes are implemented by adding an extra operation, namely re-freezing, into the original PAC encoding chain without impacting the existing blocks. Multiple constructions including a simplified version are proposed. Error-correcting performance gains are obtained.

FIGS. 1-3 and 4A-4B describe various embodiments implemented in wireless communications systems and with the use of orthogonal frequency division multiplexing (OFDM) or orthogonal frequency division multiple access (OFDMA) communication techniques. The descriptions of FIGS. 1-3 and 4A-4B are not meant to imply physical or architectural limitations to how different embodiments may be implemented. Different embodiments of the present disclosure may be implemented in any suitably arranged communications system.

FIG. 1 illustrates an example wireless network 100 within which polarization-adjusted convolutional codes with freezer may be implemented according to embodiments of the present disclosure. The embodiment of the wireless network 100 shown in FIG. 1 is for illustration only. Other embodiments of the wireless network 100 could be used without departing from the scope of this disclosure.

As shown in FIG. 1, the wireless network 100 includes a gNB 101 (e.g., base station, BS), a gNB 102, and a gNB 103. The gNB 101 communicates with the gNB 102 and the gNB 103. The gNB 101 also communicates with at least one network 130, such as the Internet, a proprietary Internet Protocol (IP) network, or other data network.

The gNB 102 provides wireless broadband access to the network 130 for a first plurality of user equipments (UEs) within a coverage area 120 of the gNB 102. The first plurality of UEs includes a UE 111, which may be located in a small business; a UE 112, which may be located in an enterprise; a UE 113, which may be a WiFi hotspot; a UE 114, which may be located in a first residence; a UE 115, which may be located in a second residence; and a UE 116, which may be a mobile device, such as a cell phone, a wireless laptop, a wireless PDA, or the like. The gNB 103 provides wireless broadband access to the network 130 for a second plurality of UEs within a coverage area 125 of the gNB 103. The second plurality of UEs includes the UE 115 and the UE 116. In some embodiments, one or more of the gNBs 101-103 may communicate with each other and with the UEs 111-116 using 5G/NR, long term evolution (LTE), long term evolution-advanced (LTE-A), WiMAX, WiFi, or other wireless communication techniques.

Depending on the network type, the term “base station” or “BS” can refer to any component (or collection of components) configured to provide wireless access to a network, such as transmit point (TP), transmit-receive point (TRP), an enhanced base station (eNodeB or eNB), a 5G/NR base station (gNB), a macrocell, a femtocell, a WiFi access point (AP), or other wirelessly enabled devices. Base stations may provide wireless access in accordance with one or more wireless communication protocols, e.g., 5G/NR 3rd generation partnership project (3GPP) NR, long term evolution (LTE), LTE advanced (LTE-A), high speed packet access (HSPA), Wi-Fi 802.11a/b/g/n/ac, etc. For the sake of convenience, the terms “BS” and “TRP” are used interchangeably in this patent document to refer to network infrastructure components that provide wireless access to remote terminals. Also, depending on the network type, the term “user equipment” or “UE” can refer to any component such as “mobile station,” “subscriber station,” “remote terminal,” “wireless terminal,” “receive point,” or “user device.” For the sake of convenience, the terms “user equipment” and “UE” are used in this patent document to refer to remote wireless equipment that wirelessly accesses a BS, whether the UE is a mobile device (such as a mobile telephone or smartphone) or is normally considered a stationary device (such as a desktop computer or vending machine).

The dotted lines show the approximate extents of the coverage areas 120 and 125, which are shown as approximately circular for the purposes of illustration and explanation only. It should be clearly understood that the coverage areas associated with gNBs, such as the coverage areas 120 and 125, may have other shapes, including irregular shapes, depending upon the configuration of the gNBs and variations in the radio environment associated with natural and man-made obstructions.

As described in more detail below, one or more of the UEs 111-116 include circuitry, programing, or a combination thereof for improving PAC codes. In certain embodiments, one or more of the BSs 101-103 include circuitry, programing, or a combination thereof to for improving PAC codes.

Although FIG. 1 illustrates one example of a wireless network, various changes may be made to FIG. 1. For example, the wireless network 100 could include any number of gNBs and any number of UEs in any suitable arrangement. Also, the gNB 101 could communicate directly with any number of UEs and provide those UEs with wireless broadband access to the network 130. Similarly, each gNB 102-103 could communicate directly with the network 130 and provide UEs with direct wireless broadband access to the network 130. Further, the gNBs 101, 102, and/or 103 could provide access to other or additional external networks, such as external telephone networks or other types of data networks.

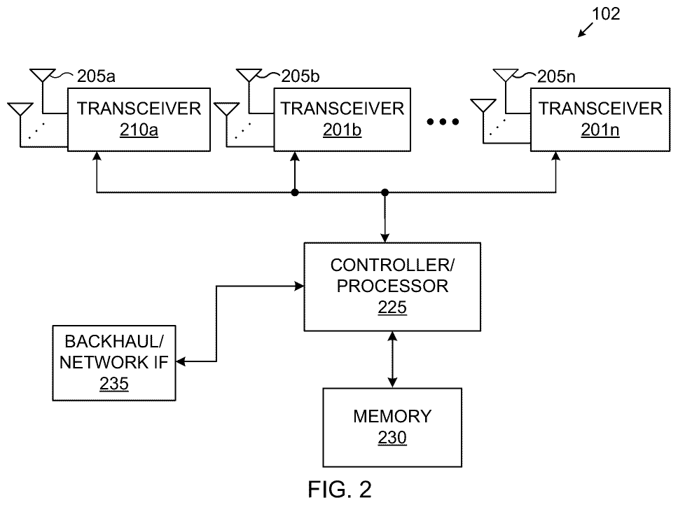

FIG. 2 illustrates an example gNB 102 within which polarization-adjusted convolutional codes with freezer may be implemented according to embodiments of the present disclosure. The embodiment of the gNB 102 illustrated in FIG. 2 is for illustration only, and the gNBs 101 and 103 of FIG. 1 could have the same or similar configuration. However, gNBs come in a wide variety of configurations, and FIG. 2 does not limit the scope of this disclosure to any particular implementation of a gNB.

As shown in FIG. 2, the gNB 102 includes multiple antennas 205a-205n, multiple transceivers 210a-210n, a controller/processor 225, a memory 230, and a backhaul or network interface 235.

The transceivers 210a-210n receive, from the antennas 205a-205n, incoming radio frequency (RF) signals, such as signals transmitted by UEs in the wireless network 100. The transceivers 210a-210n down-convert the incoming RF signals to generate IF or baseband signals. The IF or baseband signals are processed by receive (RX) processing circuitry in the transceivers 210a-210n and/or controller/processor 225, which generates processed baseband signals by filtering, decoding, and/or digitizing the baseband or IF signals. The controller/processor 225 may further process the baseband signals.

Transmit (TX) processing circuitry in the transceivers 210a-210n n and/or controller/processor 225 receives analog or digital data (such as voice data, web data, e-mail, or interactive video game data) from the controller/processor 225. The TX processing circuitry encodes, multiplexes, and/or digitizes the outgoing baseband data to generate processed baseband or IF signals. The transceivers 210a-210n up-converts the baseband or IF signals to RF signals that are transmitted via the antennas 205a-205n.

The controller/processor 225 can include one or more processors or other processing devices that control the overall operation of the gNB 102. For example, the controller/processor 225 could control the reception of uplink (UL) channel signals and the transmission of downlink (DL) channel signals by the transceivers 210a-210n in accordance with well-known principles. The controller/processor 225 could support additional functions as well, such as more advanced wireless communication functions. For instance, the controller/processor 225 could support beam forming or directional routing operations in which outgoing/incoming signals from/to multiple antennas 205a-205n are weighted differently to effectively steer the outgoing signals in a desired direction. As another example, the controller/processor 225 could support methods for improving PAC codes. Any of a wide variety of other functions could be supported in the gNB 102 by the controller/processor 225.

The controller/processor 225 is also capable of executing programs and other processes resident in the memory 230, such as processes for improving PAC codes. The controller/processor 225 can move data into or out of the memory 230 as required by an executing process.

The controller/processor 225 is also coupled to the backhaul or network interface 235. The backhaul or network interface 235 allows the gNB 102 to communicate with other devices or systems over a backhaul connection or over a network. The interface 235 could support communications over any suitable wired or wireless connection(s). For example, when the gNB 102 is implemented as part of a cellular communication system (such as one supporting 5G/NR, LTE, or LTE-A), the interface 235 could allow the gNB 102 to communicate with other gNBs over a wired or wireless backhaul connection. When the gNB 102 is implemented as an access point, the interface 235 could allow the gNB 102 to communicate over a wired or wireless local area network or over a wired or wireless connection to a larger network (such as the Internet). The interface 235 includes any suitable structure supporting communications over a wired or wireless connection, such as an Ethernet or transceiver.

The memory 230 is coupled to the controller/processor 225. Part of the memory 230 could include a RAM, and another part of the memory 230 could include a Flash memory or other ROM.

Although FIG. 2 illustrates one example of gNB 102, various changes may be made to FIG. 2. For example, the gNB 102 could include any number of each component shown in FIG. 2. Also, various components in FIG. 2 could be combined, further subdivided, or omitted and additional components could be added according to particular needs.

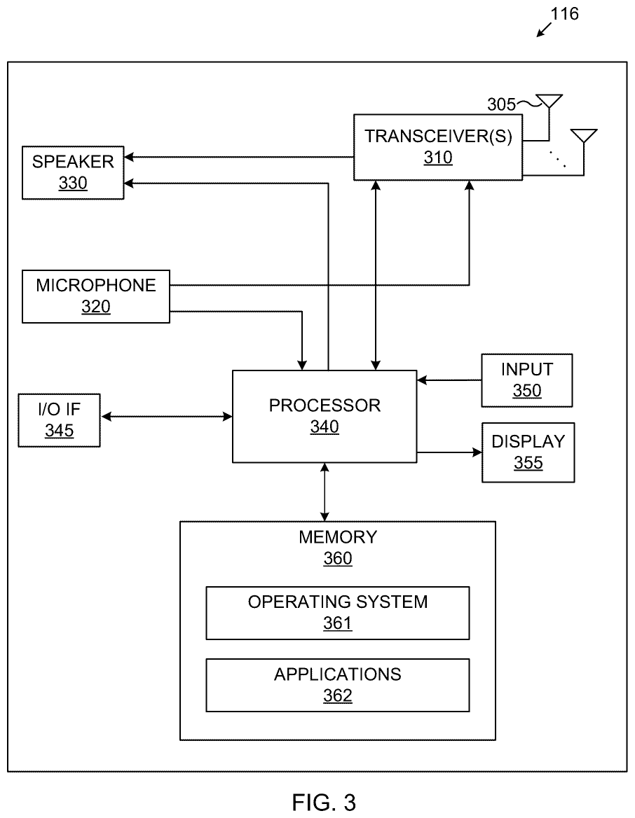

FIG. 3 illustrates an example UE 116 within which polarization-adjusted convolutional codes with freezer may be implemented according to embodiments of the present disclosure. The embodiment of the UE 116 illustrated in FIG. 3 is for illustration only, and the UEs 111-115 of FIG. 1 could have the same or similar configuration. However, UEs come in a wide variety of configurations, and FIG. 3 does not limit the scope of this disclosure to any particular implementation of a UE.

As shown in FIG. 3, the UE 116 includes antenna(s) 305, a transceiver(s) 310, and a microphone 320. The UE 116 also includes a speaker 330, a processor 340, an input/output (I/O) interface (IF) 345, an input 350, a display 355, and a memory 360. The memory 360 includes an operating system (OS) 361 and one or more applications 362.

The transceiver(s) 310 receives from the antenna(s) 305, an incoming RF signal transmitted by a gNB of the wireless network 100. The transceiver(s) 310 down-converts the incoming RF signal to generate an intermediate frequency (IF) or baseband signal. The IF or baseband signal is processed by RX processing circuitry in the transceiver(s) 310 and/or processor 340, which generates a processed baseband signal by filtering, decoding, and/or digitizing the baseband or IF signal. The RX processing circuitry sends the processed baseband signal to the speaker 330 (such as for voice data) or is processed by the processor 340 (such as for web browsing data).

TX processing circuitry in the transceiver(s) 310 and/or processor 340 receives analog or digital voice data from the microphone 320 or other outgoing baseband data (such as web data, e-mail, or interactive video game data) from the processor 340. The TX processing circuitry encodes, multiplexes, and/or digitizes the outgoing baseband data to generate a processed baseband or IF signal. The transceiver(s) 310 up-converts the baseband or IF signal to an RF signal that is transmitted via the antenna(s) 305.

The processor 340 can include one or more processors or other processing devices and execute the OS 361 stored in the memory 360 in order to control the overall operation of the UE 116. For example, the processor 340 could control the reception of DL channel signals and the transmission of UL channel signals by the transceiver(s) 310 in accordance with well-known principles. In some embodiments, the processor 340 includes at least one microprocessor or microcontroller.

The processor 340 is also capable of executing other processes and programs resident in the memory 360. For example, the processor 340 may execute processes for improving PAC codes as described in embodiments of the present disclosure. The processor 340 can move data into or out of the memory 360 as required by an executing process. In some embodiments, the processor 340 is configured to execute the applications 362 based on the OS 361 or in response to signals received from gNBs or an operator. The processor 340 is also coupled to the I/O interface 345, which provides the UE 116 with the ability to connect to other devices, such as laptop computers and handheld computers. The I/O interface 345 is the communication path between these accessories and the processor 340.

The processor 340 is also coupled to the input 350, which includes, for example, a touchscreen, keypad, etc., and the display 355. The operator of the UE 116 can use the input 350 to enter data into the UE 116. The display 355 may be a liquid crystal display, light emitting diode display, or other display capable of rendering text and/or at least limited graphics, such as from web sites.

The memory 360 is coupled to the processor 340. Part of the memory 360 could include a random-access memory (RAM), and another part of the memory 360 could include a Flash memory or other read-only memory (ROM).

Although FIG. 3 illustrates one example of UE 116, various changes may be made to FIG. 3. For example, various components in FIG. 3 could be combined, further subdivided, or omitted and additional components could be added according to particular needs. As a particular example, the processor 340 could be divided into multiple processors, such as one or more central processing units (CPUs) and one or more graphics processing units (GPUs). In another example, the transceiver(s) 310 may include any number of transceivers and signal processing chains and may be connected to any number of antennas. Also, while FIG. 3 illustrates the UE 116 configured as a mobile telephone or smartphone, UEs could be configured to operate as other types of mobile or stationary devices.

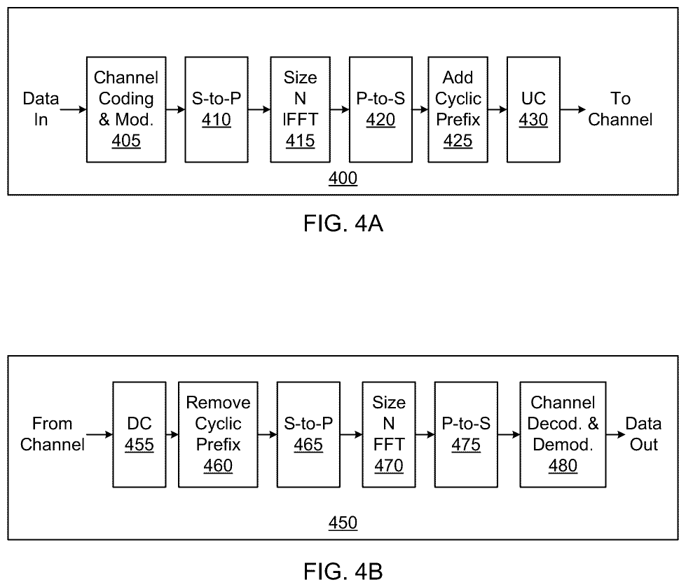

FIG. 4A and FIG. 4B illustrate an example of wireless transmit and receive paths 400 and 450, respectively, for transmitting or receiving polarization-adjusted convolutional codes with freezer according to embodiments of the present disclosure. For example, a transmit path 400 may be described as being implemented in a gNB (such as gNB 102), while a receive path 450 may be described as being implemented in a UE (such as UE 116). However, it will be understood that the receive path 450 can be implemented in a gNB and that the transmit path 400 can be implemented in a UE. In some embodiments, the transmit path 400 is configured to transmit improved PAC codes as described in embodiments of the present disclosure.

As illustrated in FIG. 4A, the transmit path 400 includes a channel coding and modulation block 405, a serial-to-parallel (S-to-P) block 410, a size N Inverse Fast Fourier Transform (IFFT) block 415, a parallel-to-serial (P-to-S) block 420, an add cyclic prefix block 425, and an up-converter (UC) 430. The receive path 250 includes a down-converter (DC) 455, a remove cyclic prefix block 460, a S-to-P block 465, a size N Fast Fourier Transform (FFT) block 470, a parallel-to-serial (P-to-S) block 475, and a channel decoding and demodulation block 480.

In the transmit path 400, the channel coding and modulation block 405 receives a set of information bits, applies coding (such as a low-density parity check (LDPC) coding), and modulates the input bits (such as with Quadrature Phase Shift Keying (QPSK) or Quadrature Amplitude Modulation (QAM)) to generate a sequence of frequency-domain modulation symbols. The serial-to-parallel block 410 converts (such as de-multiplexes) the serial modulated symbols to parallel data in order to generate N parallel symbol streams, where N is the IFFT/FFT size used in the gNB 102 and the UE 116. The size N IFFT block 415 performs an IFFT operation on the N parallel symbol streams to generate time-domain output signals. The parallel-to-serial block 420 converts (such as multiplexes) the parallel time-domain output symbols from the size N IFFT block 415 in order to generate a serial time-domain signal. The add cyclic prefix block 425 inserts a cyclic prefix to the time-domain signal. The up-converter 430 modulates (such as up-converts) the output of the add cyclic prefix block 425 to a RF frequency for transmission via a wireless channel. The signal may also be filtered at a baseband before conversion to the RF frequency.

As illustrated in FIG. 4B, the down-converter 455 down-converts the received signal to a baseband frequency, and the remove cyclic prefix block 460 removes the cyclic prefix to generate a serial time-domain baseband signal. The serial-to-parallel block 465 converts the time-domain baseband signal to parallel time-domain signals. The size N FFT block 470 performs an FFT algorithm to generate N parallel frequency-domain signals. The (P-to-S) block 475 converts the parallel frequency-domain signals to a sequence of modulated data symbols. The channel decoding and demodulation block 480 demodulates and decodes the modulated symbols to recover the original input data stream.

Each of the gNBs 101-103 may implement a transmit path 400 that is analogous to transmitting in the downlink to UEs 111-116 and may implement a receive path 450 that is analogous to receiving in the uplink from UEs 111-116. Similarly, each of UEs 111-116 may implement a transmit path 400 for transmitting in the uplink to gNBs 101-103 and may implement a receive path 450 for receiving in the downlink from gNBs 101-103.

Each of the components in FIGS. 4A and 4B can be implemented using only hardware or using a combination of hardware and software/firmware. As a particular example, at least some of the components in FIGS. 4A and 4B may be implemented in software, while other components may be implemented by configurable hardware or a mixture of software and configurable hardware. For instance, the FFT block 470 and the IFFT block 415 may be implemented as configurable software algorithms, where the value of size N may be modified according to the implementation.

Furthermore, although described as using FFT and IFFT, this is by way of illustration only and should not be construed to limit the scope of this disclosure. Other types of transforms, such as Discrete Fourier Transform (DFT) and Inverse Discrete Fourier Transform (IDFT) functions, can be used. It will be appreciated that the value of the variable N may be any integer number (such as 1, 2, 3, 4, or the like) for DFT and IDFT functions, while the value of the variable N may be any integer number that is a power of two (such as 1, 2, 4, 8, 16, or the like) for FFT and IFFT functions.

Although FIGS. 4A and 4B illustrate examples of wireless transmit and receive paths 400 and 450, respectively, various changes may be made to FIGS. 4A and 4B. For example, various components in FIGS. 4A and 4B can be combined, further subdivided, or omitted and additional components can be added according to particular needs. Also, FIGS. 4A and 4B are meant to illustrate examples of the types of transmit and receive paths that can be used in a wireless network. Any other suitable architectures can be used to support wireless communications in a wireless network.

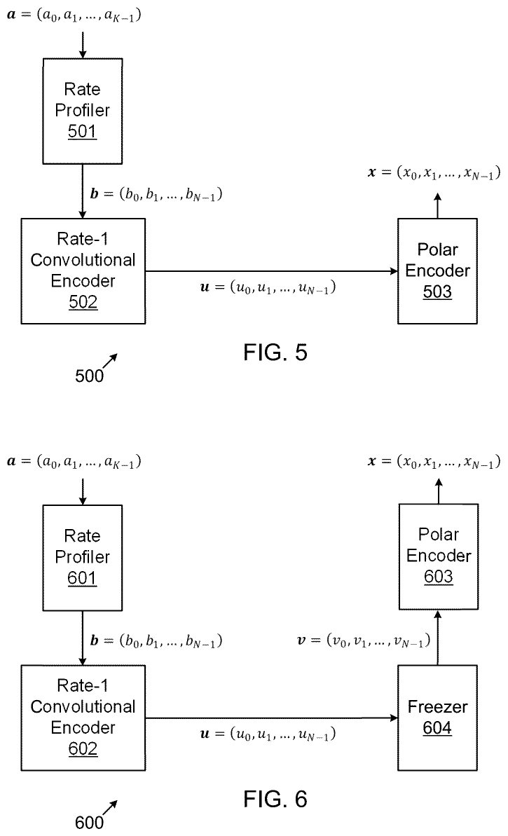

FIG. 5 illustrates an example of PAC encoder. Polar codes proposed by Arikan [1] were selected as channel codes for the control channel in some standard(s), due to their competitive performance at short block lengths, with the aid of cyclic redundancy check (CRC) and successive cancellation list (SCL) decoding. Based on polar codes, Arikan proposed polarization-adjusted convolutional (PAC) codes [2]. A PAC encoder is implemented by serially concatenating a rate profiler, e.g., a rate-1 convolutional encoder, well as a polar encoder.

Referring to FIG. 5, a=(a₀, a₁, . . . , a_{K-1}), b=(b₀, b₁, . . . , b_{N-1}), u=(u₀, u₁, . . . , u_{N-1}), and x=(x₀, x₁, . . . , x_{N-1}) are binary row vectors with length K, N, N, and N, respectively, where N=2ⁿ, n is a natural number, and K<N. a represents message bits. As shown in FIG. 5, a message a is mapped into a codeword x through the rate profiler 501, a convolutional encoder 502, and a polar encoder 503, which form the PAC encoder 500.

The notations used to help describe operation of the PAC encoder 500 are defined in TABLE 1 below:

TABLE 1

| Symbol | Definition |
|---|---|
| Z(i) | Reliability of index i, where 0 ≤ i ≤ N − 1. |
| | Z(i) is calculated using methods based on density evolution, Bhattacharyya |
| | parameter, Reed-Muller rule, etc. |
| [symbol] | Information set. |
| | Defined as a set containing K most reliable indices, i.e., [symbol] [symbol] |
| | {i_{(N-K)}, . . . , i_{(N-1)}}, where (i₍₀₎, i₍₁₎, . . . , i_{(N-1)}) is the ordered version of |
| | sequence (0, 1, . . . , N − 1) in ascending order of reliability, i.e., Z(i₍₀₎) < |
| | Z(i₍₁₎) < . . . < Z(i_{(N-1)}). For convenience, denote [symbol] ₀, [symbol] ₁, . . . , [symbol] _{K-1} as the |
| | elements of [symbol] and [symbol] ₀ < [symbol] ₁ < . . . < [symbol] _{K-1}. |
| [symbol] | Frozen set. |
| | Defined as the complement of [symbol] with respect to (0, 1, . . . , N − 1), i.e., [symbol] [symbol] |
| | {0, 1, . . . , N − 1}\ [symbol] . |
| b_{Q} | A subset of b that contains the elements whose indices belong to a set [symbol] , i.e., |
| | b_{Q} [symbol] (b_{Q}_{₀}, b_{Q}_{₁}, . . . , b_{Q}_{_{K−1}}). The notation also applied to the other vectors. |
| bin(i) | Binary form of index i, where 0 ≤ i ≤ N − 1. |
| | bin(i) [symbol] iₙ₋₁ . . . i₁i₀, where iₙ₋₁ is the most significant bit and i₀ is the least |
| | significant bit. Thus, i = Σₐ₌₀ⁿ⁻¹iₐ × 2^{a}. For example, bin(6) = 110. |
| [symbol] ᵢ | Support of index i, where 0 ≤ i ≤ N − 1. |
| | Defined as the set of indices at which bin(i) has non-zero values, i.e., |
| | [symbol] ᵢ [symbol] {∈ (0, 1, . . . , n − 1): iₐ = 1}. For example, bin(6) = 110 has non-zero |
| | values at position 1 and 2, and therefore, the support of index 6 is [symbol] ₆ = |
| | {1, 2}. |
| \|•\| | The number of elements of a set. For example, \| [symbol] ₆\| = 2. |
| gᵢ | i^{th} row of the generator matrix G_{N}, where 0 ≤ i ≤ N − 1. |
| w(gᵢ) | The weight of gᵢ. |
| | Defined as the number of non-zero elements of gᵢ. |

The input of the rate profiler 501 is a and the output of the rate profiler 501 is b. The rate profiler 501 assigns message bits and zeros via b_{Q}=a and {bᵢ=0, i∈ [symbol] }. [symbol] ⊆(0, 1, . . . , N−1) denotes the information set, [symbol] [symbol] {0, 1, . . . , N−1}\ [symbol] is the frozen set. Based on the information set [symbol] and the frozen set [symbol] , b is obtained by placing zero bits at indices belonging to frozen set, i.e., bᵢ=0, i∈ [symbol] , as well as mapping message bits a to the (most reliable) information indices b_{Q}. Note that the 1:1 relationship between a and b_{Q} is not restricted, and in this disclosure, it is assumed that the i^{th} message bit is mapped to the i^{th} element of [symbol] , i.e., [symbol] =aᵢ, where i=0, 1, . . . , K−1.

The input of the rate-1 convolutional encoder 502 is b and the output of the rate-1 convolutional encoder 502 is u. b is mapped to by a convolution operation characterized by c=(c₀, c₁, . . . , cₘ). The rate-1 convolutional code is characterized by the binary vector c=(c₀, c₁, . . . , cₘ). According to the convolution c=(c₀, c₁, . . . , cₘ), the output bit uᵢ is obtained by linearly combining the input bit bᵢ and m preceding input bits, which is shown as

$${u}_{i} = {\sum }_{j = 0}^{m} {c}_{j} {b}_{i - j} ,$$

where i=0, 1, . . . , N−1 and by convention bᵢ₋ⱼ=0 for i−j<0. b is mapped to by a convolution c=(c₀, c₁, . . . , cₘ)

The input of the polar encoder 503 is u and the output of the polar encoder 503 is x. The polar encoder 503 maps u to x through the generator (square) matrix

$${G}_{N} = {[ \begin{matrix}1 & 0 \\ 1 & 1\end{matrix} ]}^{{⊗}_{n}} ,$$

i.e., x=u×G_{N}, where ⊗ is the Kronecker product.

Minimum-weight codewords may be introduced due to convolution. For example, for N=8 and K=4, a generator matrix G₈ may be (the left-most column stores indices, while the remaining columns are generator matrix values):

| | | | | | | | | |
|---|---|---|---|---|---|---|---|---|
| 0 | 1 | 0 | 0 | 0 | 0 | 0 | 0 | 0 |
| 1 | 1 | 1 | 0 | 0 | 0 | 0 | 0 | 0 |
| 2 | 1 | 0 | 1 | 0 | 0 | 0 | 0 | 0 |
| 3 | 1 | 1 | 1 | 1 | 0 | 0 | 0 | 0 |
| 4 | 1 | 1 | 0 | 0 | 1 | 1 | 0 | 0 |
| 5 | 1 | 0 | 1 | 0 | 1 | 0 | 1 | 0 |
| 6 | 1 | 0 | 1 | 0 | 1 | 0 | 1 | 0 |
| 7 | 1 | 1 | 1 | 1 | 1 | 1 | 1 | 1 |

For i=1 of the above generator matrix, the weight of that first row is 2. For j=3, | [symbol] ₃\ [symbol] ₁|=1 and the weight of (g₁⊕g₃) is 2. For j=6, | [symbol] ₆\ [symbol] ₁|=2 and the weight of (g₁⊕g₆) is 4.

For the information set [symbol] =[1, 5, 6, 7], a resulting polar codeword may be [x₀, . . . , x₇]=[0, a₀, 0, 0, 0, a₁, a₂, a₃]×G₈. Due to the convolution operation, however, the bits placed at frozen indices 2, 3, and 4 are no longer fixed to zeros. Therefore, a minimum-weight codeword may be generated (e.g., the summation of row 1 and row 3 results in a weight-2 codeword). The present disclosure solves that potential issue by selectively re-freezing the bits at frozen indices to zeros after convolution operation.

Due to the convolution operation in PAC codes, the bits assigned to some of the frozen indices are no longer fixed to zeros, which may induce low-weight codewords, and therefore weaken the error-correcting performance. An extra operation, namely freezing, is added between the rate-1 convolutional encoder 502 and the polar encoder 503. The freezer assigns zeros to carefully selected frozen indices, such that the rows of the polar generator matrix which may induce the low-weight codewords are not involved in generating codewords.

FIG. 6 illustrates an example of polarization-adjusted convolutional coding with freezer in accordance with embodiments of the present disclosure. The embodiment of the PAC encoder with freezer 600 shown in FIG. 6 is for illustration only. Other embodiments of the PAC encoder with freezer 600 could be used without departing from the scope of this disclosure.

FIG. 6 depicts an example PAC encoder with freezer 600 in an embodiment of the disclosure. The PAC encoder with freezer 600 is implemented by serially concatenating a rate profiler 601, a rate-1 convolutional encoder 602, and a re-freezer 604, as well as a polar encoder 603. The rate profiler 601, the rate-1 convolutional encoder 602, and the polar encoder 603 operate in the same manner as described above for the rate profiler 501, the rate-1 convolutional encoder 502, and the polar encoder 503, respectively.

Referring to FIG. 6, a=(a₀, a₁, . . . , a_{K-1}), b=(b₀, b₁, . . . , b_{N-1}), u=(u₀, u₁, . . . , u_{N-1}), and x=(x₀, x₁, . . . , x_{N-1}) are binary row vectors with length K, N, N, and N, respectively, where N=2ⁿ, n is a natural number, and K<N. T

In the PAC encoder with freezer 600 shown in FIG. 6, the input of the rate profiler 601 is a and the output of the rate profiler 601 is b. Based on the information set [symbol] and the frozen set [symbol] , b is obtained by placing zero bits at indices belonging to frozen set, i.e., bᵢ=0, i∈ [symbol] , as well as message bits a at indices belonging to the information set, i.e., b_{Q}_{ᵢ}=aᵢ for i=0, 1, . . . , K−1.

The input of the rate-1 convolutional encoder 602 is b and the output of the rate-1 convolutional encoder 602 is u. The rate-1 convolutional code is characterized by a binary vector c=(c₀, c₁, . . . , cₘ). According to the convolution c=(c₀, c₁, . . . , cₘ), the output bit uᵢ is obtained by linearly combining the input bit bᵢ and m preceding input bits, which is shown as

$${u}_{i} = {\sum }_{j = 0}^{m} {c}_{j} {b}_{i - j} ,$$

where i=0, 1, . . . , N−1 and by convention bᵢ₋ⱼ=0 for i−j<0.

The input of the freezer 604 is u and the output of the freezer is v. Based on a subset of [symbol] , denoted [symbol] , the freezer 604 produces zero bits or directly passes the input bits. Specifically, the output is

$${v}_{i} = \{ \begin{matrix}0 , & if i ∈ , \\ {u}_{i} , & otherwise\end{matrix} .$$

The subset [symbol] ⊆ [symbol] is called the re-frozen set. The construction of the subset [symbol] is described below.

The input of the polar encoder 603 is v and the output of the polar encoder 603 is x. The polar encoder 603 maps v to x through the generator matrix

$${G}_{N} = {[ \begin{matrix}1 & 0 \\ 1 & 1\end{matrix} ]}^{{⊗}_{n}} ,$$

i.e., x=v×G_{N}, where ⊗ is the Kronecker product.

The processing by the PAC encoder with freezer 600 may be performed by either the controller/processor 225 in FIG. 2 or the processor 340 of FIG. 3. The input of the PAC encoder with freezer 600 may be the “Data Out” from the receive path 450 of FIG. 4B. The output of the PAC encoder with freezer 600 may be the “Data In” to the transmit path 400 of FIG. 4A.

In the following, an embodiment of the present disclosure to construct the subset [symbol] is presented. It is possible to generate a minimum-weight codeword when combining a row g; with the minimum weight as well as a row j with j>i and | [symbol] ⱼ\ [symbol] ᵢ>1. Therefore, to remove this minimum-weight codeword, row j can be excluded from the combination by simply freezing the bit at j to zero. Therefore, the subset [symbol] contains the frozen indices j which satisfy j>i and | [symbol] ⱼ\ [symbol] ᵢ|>1.

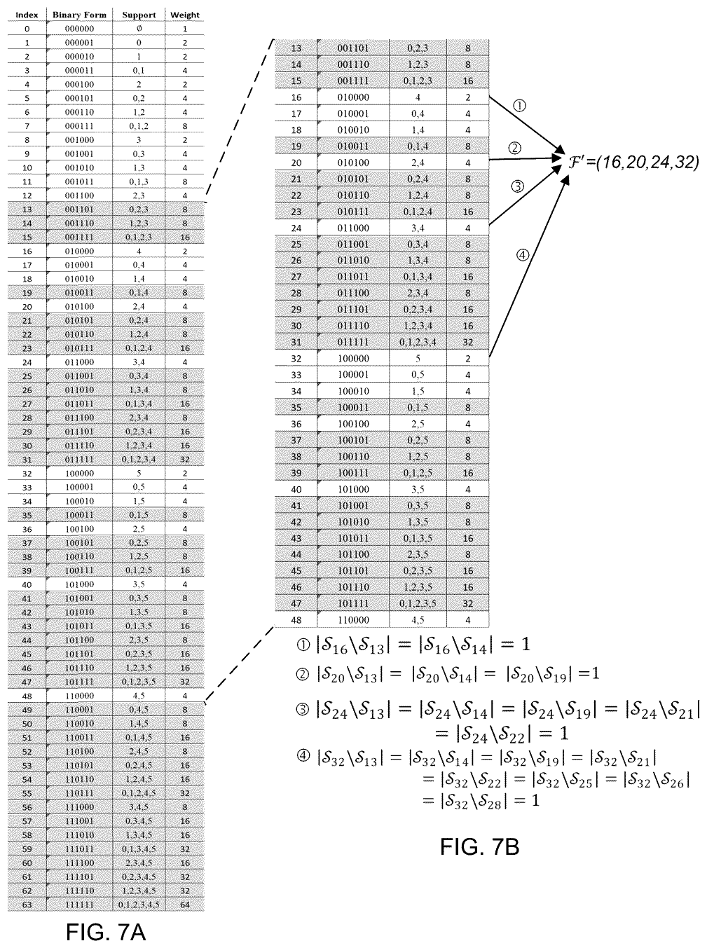

FIGS. 7A-7B illustrates an example construction of the subset [symbol] for the freezer in an exemplary embodiment of the present disclosure. In this example, N=64 and K=40. Referring to FIG. 7A, in which the indices highlighted in gray within of table depicted belong to the information set, the first column stores the row indices of a generator matrix G₆₄, and the second column stores the binary form of that index. The third column stores the support of the respective index. The fourth column stores the row weight of a generator matrix G₆₄, which indicates that the minimum weight is 8 for the rows whose indices belong to the information set. A frozen index j is considered a candidate for inclusion within the subset [symbol] unless there is a smaller information index with the minimum weight. In the example of FIG. 7A, there is no information index with the minimum weight that is smaller than the frozen indices (0, 1, 2, . . . , 12). Therefore, only the frozen indices in FIG. 7B are considered to be included in the subset [symbol] of the frozen indices.

In FIG. 7B, starting at the first frozen index (16) that is above 12, a frozen index j is included in the subset [symbol] if that index j satisfies | [symbol] ⱼ\ [symbol] ᵢ|=1 for all information indices i which are smaller than j and have the minimum weight. For example, index 20 is included into the subset [symbol] , since | [symbol] ₂₀\ [symbol] ₁₃|=| [symbol] ₂₀\ [symbol] ₁₄|=| [symbol] ₂₀\ [symbol] ₁₉|=1, where indices 13, 14 and 19 are the minimum-weight information indices smaller than the frozen index 20. Similarly, indices 16, 24 and 32 are also included in the subset [symbol] , such that (for the example of FIG. 7B) the subset [symbol] =(16, 20, 24, 32). That is, for index 16, | [symbol] ₁₆\ [symbol] ₁₃|=| [symbol] ₁₆\ [symbol] ₁₄|=1; for index 24, | [symbol] ₂₄\ [symbol] ₁₃|=| [symbol] ₂₄\ [symbol] ₁₄₁=| [symbol] ₂₄\ [symbol] ₁₉|=| [symbol] ₂₄\ [symbol] ₂₁|=| [symbol] ₂₄\ [symbol] ₂₂|=1; and for index 32, | [symbol] ₃₂\ [symbol] ₁₃|=| [symbol] ₃₂\ [symbol] ₁₄|=| [symbol] ₃₂\ [symbol] ₁₉|=| [symbol] ₃₂\ [symbol] ₂₁|=| [symbol] ₃₂\ [symbol] ₂₂|=| [symbol] ₃₂\ [symbol] ₂₅|=| [symbol] ₃₂\ [symbol] ₂₆|=| [symbol] ₃₂\ [symbol] ₂₈|=1.

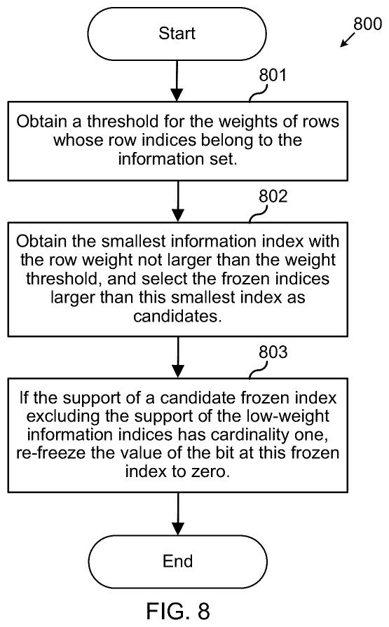

FIG. 8 is a high level flowchart of a process to choose the frozen indices in accordance with embodiments of the present disclosure. The process 800 illustrated in FIG. 8 is for illustration only, and FIG. 8 does not limit the scope of this disclosure to any particular implementation. The process 800 may be performed by either the controller/processor 225 in FIG. 2 or the processor 340 of FIG. 3.

FIG. 8 illustrates an example flowchart of a method 800, showing the construction of the subset [symbol] in an embodiment of the disclosure. Referring to FIG. 8, at operation 801, a threshold d for the weights of rows whose row indices belong to the information set is obtained and shown as

$$d = min ( \{ w ( {g}_{i} ) , i ∈ \} ) .$$

At operation 802, the smallest information index with row weight not larger than d is obtained and shown as

$${i}_{min} = min ( \{ i ∈ : w ( {g}_{i} ) \leq d \} ) .$$

The frozen indices larger than iₘᵢₙ are selected to form a set:

$$= \{ j ∈ : j > {i}_{min} \} .$$

Operation 802 excludes from consideration a frozen index j if there is no minimum-weight information index smaller than j, as shown in the example in FIG. 7B.

At operation 803, for each index j= [symbol] , the information indices which are smaller than j and have row weight not larger than d are selected to form a set:

$${ℋ}_{j} = \{ i ∈ Q : i < j and w ( {g}_{i} ) \leq d \} .$$

If | [symbol] ⱼ\ [symbol] ᵢ|=1 for all i∈ [symbol] ⱼ, index j is included into set [symbol] , and hence the value vⱼ of the bit at index j is re-frozen to zero, i.e., vⱼ=0.

Although FIG. 8 illustrates one example process 800 for choosing the frozen indices, various changes may be made to FIG. 8. For example, while shown as a series of steps, various steps in FIG. 8 may overlap, occur in parallel, or occur any number of times.

In one embodiment of the disclosure, at operation 801, the value of the weight threshold d can be selected as the second smallest row weight, i.e., d=2¹*min({w(gᵢ), i∈ [symbol] }), the third smallest row weight, i.e., d=2¹*min({w(gᵢ), i∈ [symbol] }) and so on, while the other operations can be identical or similar to those described above.

In one embodiment of the disclosure, at operation 803, index j can be included in the subset [symbol] if there exists an index i∈ [symbol] ⱼ such that | [symbol] ⱼ\ [symbol] ᵢ|=1, while the other operations can be identical or similar to the operations described above.

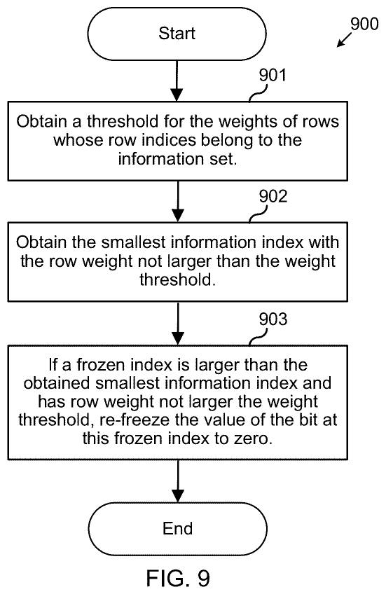

FIG. 9 is a high level flowchart of an alternative process to choose the frozen indices in accordance with embodiments of the present disclosure. The process 900 illustrated in FIG. 9 is for illustration only, and FIG. 9 does not limit the scope of this disclosure to any particular implementation. The process 900 may be performed by either the controller/processor 225 in FIG. 2 or the processor 340 of FIG. 3.

FIG. 9 is an example flowchart showing the construction of the subset [symbol] in one embodiment of the invention. Referring to FIG. 9, at operation 901, a threshold d for the weights of rows whose row indices belong to information set is obtained as described above.

At operation 902, the smallest information index with row weight not larger than d is obtained and shown as

$${i}_{min} = min ( \{ i ∈ : w ( {g}_{i} ) \leq d \} ) .$$

At operation 903, the frozen indices that are larger than iₘᵢₙ and have row weight not larger than d can be included in the subset [symbol] , that is

$$= \{ i ∈ : w ( {g}_{i} ) \leq d and i > {i}_{min} \} .$$

Although FIG. 9 illustrates one example process 900 for choosing the frozen indices, various changes may be made to FIG. 9. For example, while shown as a series of steps, various steps in FIG. 9 may overlap, occur in parallel, or occur any number of times.

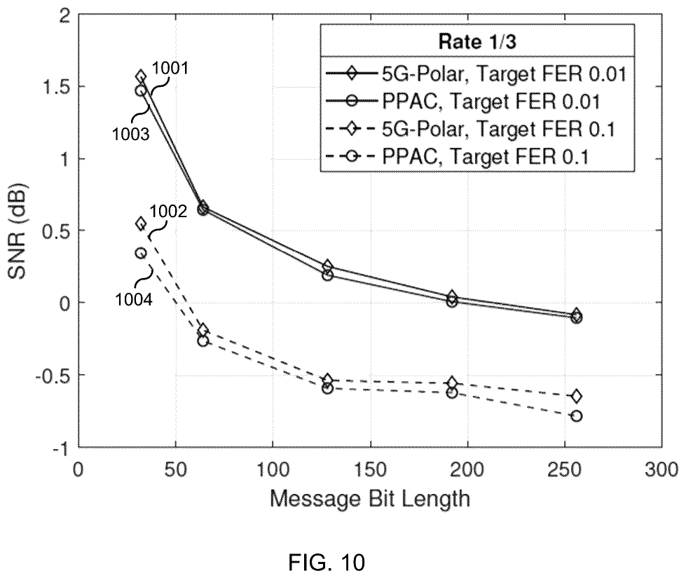

FIG. 10 compares performance of polar codes with and without the encoding method according to embodiments of the present disclosure, in terms of the required signal-to-noise (SNR) in decibels (dB) for achieving a target frame error rate (FER). The frame error rate comparison is presented for polar codes 1001 and 1002 without PAC with freezer and polar codes 1003 and 1004 with PAC with freezer (labeled “PPAC”) in accordance with embodiments of the present disclosure. The code rate is 1/3, the target FER are 0.1 for polar codes 1002 and 1004 and 0.01 for polar codes 1001 and 1003, and the message sizes are 32, 64, 128, 192 and 256. List-8 successive cancellation list (SCL) decoding is applied. Approximate 0.2 dB gain or more can be achieved, when the message sizes are 32 and 256.

Although the present disclosure has been described with exemplary embodiments, various changes and modifications may be suggested to one skilled in the art. It is intended that the present disclosure encompass such changes and modifications as fall within the scope of the appended claims. None of the description in this application should be read as implying that any particular element. step, or function is an essential element that must be included in the claims scope. The scope of patented subject matter is defined by the claims.

What is claimed is:

1. A method for encoding, the method comprising:
receiving a plurality of information bits (k), wherein k is a positive integer;
generating a plurality of convolutionally encoded bits (n) by performing a convolutional encoding operation on the plurality of information bits and a plurality of frozen bits (n−k), wherein n is a positive integer;
performing a refreezing operation on the plurality of convolutionally encoded bits, wherein the refreezing operation includes dynamically assigning zeros to selected frozen indices such that a number of low weight codewords is reduced;
generating a plurality of polar encoded bits by performing a polar encoding operation on an output of the refreezing operation; and
providing the plurality of polar encoded bits for transmission or storage.

2. The method of claim 1, wherein dynamically assigning zeros to the selected frozen indices further comprises:
obtaining a threshold for weights of rows, wherein an index of the rows belongs to the information bits;
obtaining a smallest index of the information bits with a weight of a row not larger than the threshold;
identifying frozen indices as candidate frozen indices such that indexes of the candidate frozen indices are larger than the smallest index; and
refreezing a value of a bit at the candidate frozen index to zero when a support of the candidate frozen index, excluding a support of an index corresponding to information bits that has a row weight less than or equal to the threshold, has cardinality equal to one.

3. The method of claim 2, wherein the threshold for the weights of rows corresponds to a minimum weight.

4. The method of claim 1, wherein dynamically assigning zeros to the selected frozen indices further comprises:
obtaining a threshold for weights of rows, wherein an index of the rows belong to the information bits;
obtaining a smallest index of the information bits with a weight of a row not larger than the threshold; and
refreezing a value of a bit at the frozen index to zero when (i) a weight of the row corresponding to the frozen index is less than or equal to the threshold, and (ii) the frozen index is larger than the smallest index.

5. The method of claim 1, wherein the output v of the refreezing operation is
$${v}_{i} = \{ \begin{matrix}0 , & if i ∈ , \\ {u}_{i} , & otherwise\end{matrix} .$$
where i=0, 1, . . . , N−1, N=2ⁿ is a length of the convolutionally encoded bits u, uᵢ is an ith bit of the convolutionally encoded bits u, uᵢ is an ith bit of the output v of the refreezing operation, and [symbol] is the selected frozen indices.

6. The method of claim 1, wherein the selected frozen indices j satisfy j>i and
$$\vert {j}_{} \backslash {i}_{} \vert > 1 ,$$
where [symbol] ᵢ is support of a set for index i and [symbol] ⱼ is support of a set for index j, |·| is a number of elements of a set, i=0, 1, . . . , N−1, and N is a length of the convolutionally encoded bits.

7. The method of claim 6, wherein the support of a set are indices at which a binary form of an index has non-zero values.

8. The method of claim 1, wherein the low weight codewords are minimum weight codewords.

9. An encoding apparatus, comprising:
a transmitter; and
a processor configured to:
receive a plurality of information bits (k), wherein k is a positive integer,
generate a plurality of convolutionally encoded bits (n) by performing a convolutional encoding operation on the plurality of information bits and a plurality of frozen bits (n−k), wherein n is a positive integer,
perform a refreezing operation on the plurality of convolutionally encoded bits, wherein the refreezing operation includes dynamically assigning zeros to selected frozen indices such that a number of low weight codewords is reduced, and
generate a plurality of polar encoded bits by performing a polar encoding operation on an output of the refreezing operation,
wherein the plurality of polar encoded bits are provided for transmission or storage.

10. The encoding apparatus of claim 9, wherein, in dynamically assigning zeros to the selected frozen indices, the processor is further configured to:
obtain a threshold for weights of rows, wherein an index of the rows belongs to the information bits;
obtain a smallest index of the information bits with a weight of a row not larger than the threshold;
identify frozen indices as candidate frozen indices such that indexes of the candidate frozen indices are larger than the smallest index; and
refreeze a value of a bit at the candidate frozen index to zero when a support of the candidate frozen index, excluding a support of an index corresponding to information bits that has a row weight less than or equal to the threshold, has cardinality equal to one.

11. The encoding apparatus of claim 10, wherein the threshold for the weights of rows corresponds to a minimum weight.

12. The encoding apparatus of claim 9, wherein, in dynamically assigning zeros to the selected frozen indices, the processor is further configured to:
obtain a threshold for weights of rows, wherein an index of the rows belong to the information bits;
obtain a smallest index of the information bits with a weight of a row not larger than the threshold; and
refreeze a value of a bit at the frozen index to zero when (i) a weight of the row corresponding to the frozen index is less than or equal to the threshold, and (ii) the frozen index is larger than the smallest index.

13. The encoding apparatus of claim 9, wherein the output v of the refreezing operation is
$${v}_{i} = \{ \begin{matrix}0 , & if i ∈ \\ {u}_{i} , & otherwise\end{matrix} .$$
where i=0, 1, . . . , N−1, N=2ⁿ is a length of the convolutionally encoded bits u, uᵢ is an ith bit of the convolutionally encoded bits u, uᵢ is an ith bit of the output v of the refreezing operation, and [symbol] is the selected frozen indices.

14. The encoding apparatus of claim 9, wherein the selected frozen indices j satisfy j>i and
$$\vert {j}_{} \backslash {i}_{} \vert > 1 ,$$
where [symbol] ᵢ is support of a set for index i and [symbol] ⱼ is support of a set for index j, |·| is a number of elements of a set, i=0, 1, . . . , N−1, and N is a length of the convolutionally encoded bits.

15. The encoding apparatus of claim 14, wherein the support of a set are indices at which a binary form of an index has non-zero values.

16. The encoding apparatus of claim 9, wherein the low weight codewords are minimum weight codewords.

17. A decoding apparatus, comprising:
a transceiver configured to receive a polar code with refrozen indices from a communication channel; and
a processor configured to perform successive cancellation list decoding of the polar code with refrozen indices, wherein the polar code with refrozen indices is generated by:
receiving a plurality of information bits (k), wherein k is a positive integer,
generating a plurality of convolutionally encoded bits (n) by performing a convolutional encoding operation on the plurality of information bits and a plurality of frozen bits (n−k), wherein n is a positive integer,
performing a refreezing operation on the plurality of convolutionally encoded bits, wherein the refreezing operation includes dynamically assigning zeros to selected frozen indices such that a number of low weight codewords is reduced, and
generating a plurality of polar encoded bits by performing a polar encoding operation on an output of the refreezing operation.

18. The decoding apparatus of claim 17, wherein dynamically assigning zeros to the selected frozen indices further comprises:
obtaining a threshold for weights of rows, wherein an index of the rows belongs to the information bits;
obtaining a smallest index of the information bits with a weight of a row not larger than the threshold;
identifying frozen indices as candidate frozen indices such that indexes of the candidate frozen indices are larger than the smallest index; and
refreezing a value of a bit at the candidate frozen index to zero when a support of the candidate frozen index, excluding a support of an index corresponding to information bits that has a row weight less than or equal to the threshold, has cardinality equal to one.

19. The decoding apparatus of claim 18, wherein the threshold for the weights of rows corresponds to a minimum weight.

20. The decoding apparatus of claim 17, wherein dynamically assigning zeros to the selected frozen indices further comprises:
obtaining a threshold for weights of rows, wherein an index of the rows belong to the information bits;
obtaining a smallest index of the information bits with a weight of a row not larger than the threshold; and
refreezing a value of a bit at the frozen index to zero when (i) a weight of the row corresponding to the frozen index is less than or equal to the threshold, and (ii) the frozen index is larger than the smallest index.
